(19) United States
(12) Patent Application Publication
(10) Pub. No.: US 2026/0252527 A1
(43) Pub. Date: Aug. 27, 2026

(54) CUSTOMIZABLE NETWORK INFRASTRUCTURE CHIPLET

(71) Applicant: MIPS Tech, LLC, San Jose, CA (US)

(72) Inventors: Prakash C. Jain, Fremont, CA (US); Durgesh Srivastava, Cupertino, CA (US)

(21) Appl. No.: 19/548,689

(22) Filed: Feb. 24, 2026

Related U.S. Application Data
(60) Provisional application No. 63/763,008, filed on Feb. 25, 2025.

(51) Int. Cl. G06F 15/78

(52) U.S. Cl. CPC G06F 15/7867

(57) ABSTRACT

Disclosed are a design system, method and computer program product for integrated circuits (ICs) including network infrastructure ICs. The system includes a memory, which stores a library including a library element for a customizable network infrastructure chiplet. The library element includes: multiple blocks including at least a subsystem block and a cores block; a subsystem menu for the subsystems block; and a softcores menu for cores block. The subsystems menu includes networking subsystems. The softcores menu includes softcores optimized for networking functions. The system further includes a processor, which generates a layout for a customized network infrastructure chiplet using the library element. This layout includes, within the subsystems block, at least one subsystem selected from the subsystems menu; and, within the cores block, at least one softcore selected from the softcores menu and optimized for at least one networking function (e.g., given the selected sub-system(s)).

### BACKGROUND

The present disclosure relates to network infrastructure chiplets and, more particularly, to embodiments of a design system, method, and computer program product for developing a customized layout for a network infrastructure chiplet.

A chiplet refers to a modular integrated circuit (IC). Such chiplets are often designed to perform specific functions and to be combined with other chiplets into a single, more complex, package to form a system-on-chip (SOC). For example, network infrastructures for various different types of applications (e.g., for artificial intelligence (AI) and/or machine learning (ML) applications, industrial applications, automotive applications, etc.) may include network infrastructure (infra) chiplets designed to perform specific networking functions. One or more network infra chiplets can be mounted on a substrate (e.g., an interposer) of a packaged device (e.g., a SOC) that is included within the network infrastructure. As the demand for improved performance, power, and area (PPA) of these applications increases, so does the demand for improved PPA in the network infrastructures used to implement them. Unfortunately, a bottleneck in the network infrastructure design process (i.e., a stage where the workflow in the network infrastructure design process slows) can be the development of specialized network infrastructure chiplets.

### SUMMARY

Disclosed herein are embodiments of a design system for a network infrastructure. The design system can include a memory storing a library. The library can include multiple library elements including a library element specifically for a customizable network infrastructure chiplet. The library element for the customizable network infrastructure chiplet can include: multiple blocks including a subsystems block and a cores block; a subsystems menu for the subsystems block; and a softcores menu for the cores block. The design system can also include a processor in communication with the memory. The processor can generate a design layout for a customized network infrastructure chiplet using the library element. This design layout can include, within the subsystems block, at least one subsystem selected from the subsystems menu; and, within the cores block, at least one softcore optimized for at least one networking function and selected from the softcores menu.

Also disclosed herein are embodiments of a design method for a network infrastructure. The design method can include accessing, by a processor from memory, a library. The library can include multiple library elements including a library element specifically for a customizable network infrastructure chiplet. The library element for the customizable network infrastructure chiplet can include: multiple blocks including a subsystems block and a cores block; a subsystems menu for the subsystems block; and a softcores menu for the cores block. The method can further include generating, by the processor, a layout for a customized network infrastructure chiplet using the library element. This layout can include, within the subsystems block, at least one subsystem selected from the subsystems menu; and, within the cores block, at least one softcore optimized for at least one networking function and selected from the softcores menu.

Also disclosed herein are embodiments of a computer program product comprising a non-transitory computer readable storage medium having program instructions embodied therewith. The program instructions can be executable by a processor to cause the processor to perform the above-described method.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating embodiments of a computer-aided integrated circuit (IC) design system including a library with a library element for a customizable network infrastructure chiplet;

FIG. 2 is an illustration representative of the library element for the customizable network infrastructure chiplet;

FIG. 3 is a flow diagram illustrating embodiments of a design method employing the library element to generate a layout for a customized network infrastructure chiplet;

FIG. 4 is an illustration of an example artificial intelligence (AI) or machine learning (ML) network including a network infrastructure suitable for incorporating customized network infrastructure chiplet(s);

FIG. 5 is an illustration of an example industrial or automotive network including a network infrastructure suitable for incorporating customized network infrastructure chiplet(s);

FIG. 6 is a layout drawing illustrating a customized network infrastructure chiplet generated according to disclosed embodiments;

FIG. 7 is an expanded view of a packet processing subsystem within the customized network infrastructure chiplet of FIG. 6; and

FIG. 8 is a schematic diagram illustrating an example of a hardware environment for implementing aspects of the disclosed embodiments.

### DETAILED DESCRIPTION

As mentioned above, a chiplet refers to a modular integrated circuit (IC). Such chiplets are often designed to perform specific functions and to be combined with other chiplets into a single, more complex, package to form a system-on-chip (SOC). For example, network infrastructures for various different types of applications (e.g., for artificial intelligence (AI) and/or machine learning (ML) applications, industrial applications, automotive applications, etc.) may include network infrastructure (infra) chiplets designed to perform specific networking functions. One or more network infra chiplets can be mounted on a substrate (e.g., an interposer) of a packaged device (e.g., a SOC) that is included within the network infrastructure. As the demand for improved performance, power, and area (PPA) of these applications increases, so does the demand for improved PPA in the network infrastructures used to implement them. Unfortunately, a bottleneck in the network infrastructure design process (i.e., a stage where the workflow in the network infrastructure design process slows) can be the development of specialized network infrastructure chiplets.

In view of the foregoing, disclosed herein are embodiments of a design system, method, and computer program product for integrated circuits (ICs) including, but not limited to, network infrastructure ICs with customized network infrastructure chiplet(s). The disclosed embodiments include accessing (e.g., from a library stored in memory) a library element for the customizable network infrastructure chiplet. The library element can include multiple blocks including, but not limited to, a subsystem block, a cores block, and a network-on-chip (NOC) fabric block that facilitates communication between all other blocks. The library element can further include multiple menus including, but not limited to, a subsystem menu for the subsystems block and a softcores menu for cores block. The subsystems menu can include multiple networking subsystems for one or more different types of networking applications (e.g., artificial intelligence (AI) and machine learning (ML) networking applications, industrial networking subsystems, and/or automotive networking applications). The softcores menu can include multiple softcores, each optimized for one or more different networking functions. The disclosed embodiments can further include generating (e.g., by a processor in communication with the memory and using the library element) a design layout for a customized network infrastructure chiplet. This design layout can include, within the subsystems block, at least one subsystem selected from the subsystems menu; and, within the cores block, at least one softcore selected from the softcores menu and optimized for at least one networking function (e.g., given the selected sub-system(s)). The disclosed design system and method embodiments provide for the development of a customized network infrastructure chiplet for inclusion in network infrastructures of diverse networking applications (including, but not limited to, AI/ML, industrial and automotive networking applications) within a relatively fast turn-around-time (TAT) while still providing the necessary flexibility for meeting performance, power and/or area (PPA) specifications.

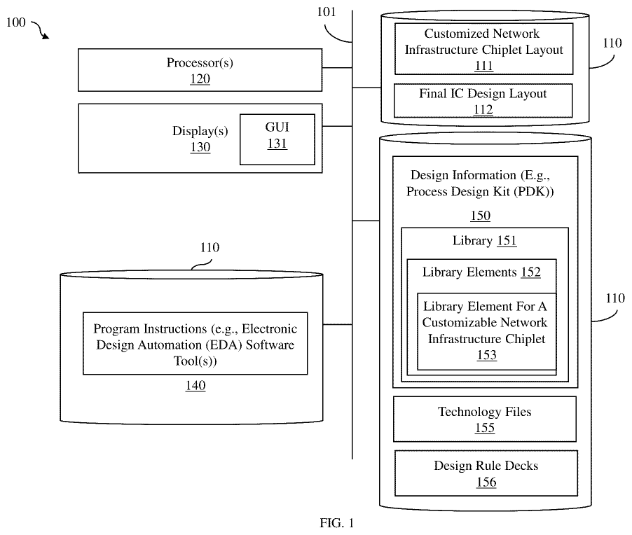

More particularly, referring to FIG. 1, disclosed herein are embodiments of a computer-aided design (CAD) system for integrated circuits (ICs) (hereinafter referred to as system 100) including for network infrastructure ICs, which include a customized network infrastructure chiplet. System 100 can include one or more processors 120, one or more displays 130 (including a graphic user interface (GUI) 131), and one or more memories 110 (e.g., one or more non-transitory computer readable storage mediums or devices). The various components of system 100 including, but not limited to, processor(s) 120, display(s) 130, and memories 110 can be interconnected over a network 101 including, for example, a system bus and, optionally, a wired or wireless network.

Memory 110 can store sets of program instructions 140, which are readable by a processor 120 and can be executed by a processor 120 during different stages in a design flow. The sets of program instructions 140 can be in the form of design automation (EDA) tools (e.g., specialized software program(s)). Exemplary EDA tools can include, but are not limited to, any of a schematics generation tool, a floorplanning tool, a power planning tool, an input/output pin placement tool, a clock planning tool, a wire routing tool, a timing analysis tool, a timing closure tool, a design verification tools (e.g., a layout versus schematic (LVS) checking tool, etc.), design rule checking (DRC) tool(s), simulator(s), etc. Those skilled in the art will recognize that such tools are well known. Thus, details thereof have been omitted from the specification to allow the reader to focus on the salient aspects of the disclosed embodiments.

Memory 110 can further store design information 150, which is accessible by a processor 120 and usable during different stages in the design flow. Design information 150 can, for example, be in the form of a process design kit (PDK). The design information 150 can include, but is not limited to, technology files 155 for a specific technology node, rule decks 156, and a library 151. Those skilled in the art will recognize that technology files refer to files that define the layers and devices that are available for a particular fabrication process as well as the generic physical and electrical rules for the specific technology node. Furthermore, design rule decks refer to discrete sets of design rules (also called run sets), where each rule deck includes design rules that are applicable to one or more of the particular processes in the design flow.

A library 151 is a database that defines multiple different library elements 152 and the symbols thereof that can be incorporated into a schematic diagram of an IC under design in the specific technology node. Each library element 152 can represent a pre-designed and pre-verified IC component such as a cell and/or some other modular, reusable piece of intellectual property (e.g., for a chiplet). A library element 152 could represent, for example, a single device (e.g., a transistor, capacitor, resistor, etc.) or other feature (e.g., an isolation region, etc.), or multiple interconnected devices or features (e.g., a logic gate, etc.). A library element 152 can further be associated with additional design information optionally including, but not limited to, timing, power and noise information. Within library 151, library elements 152 could include, for example: standard library elements (e.g., standard cells); previously customized and stored library elements (e.g., customized cells); and customizable library elements. A customizable library element could include, for example, a parameterized cell (Pcell) and, more particularly, a cell in which one or more parameters, such as size, width, length, etc., are selectable. Those skilled in the art will recognize that standard cells and Pcells are well known. Thus, the details thereof have been omitted from this specification in order to allow the reader to focus on the salient aspects of the disclosed embodiments. Additionally, in the disclosed embodiments at least one such customizable library element included within library 151 could be a library element 153 for a customizable network infrastructure chiplet (discussed in greater detail below).

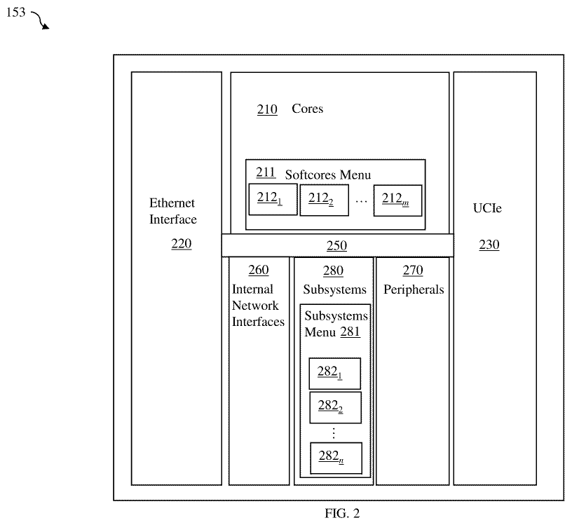

As mentioned above, network infrastructures for various different types of applications (e.g., for artificial intelligence (AI) and/or machine learning (ML) applications, industrial applications, automotive applications, etc.) may include network infrastructure (infra) chiplets designed to perform specific networking functions. FIG. 2 is an illustration representative of a library element (LE) 153 for a customizable network infrastructure chiplet (also referred to herein as customizable LE 153). As illustrated in FIG. 2, customizable LE 153 can include multiple blocks. These blocks can include but are not limited to: a cores block 210, an Ethernet interface block 220, a Universal Chiplet Interconnect Express (UCIe) block 230; a network-on-chip (NOC) fabric block 250; an internal network interfaces block 260; a peripherals block 270; and a subsystems block 280.

At least some of the blocks can include standard components found within a network infrastructure chiplet. For example, cores block 210 can include one or more central processing unit (CPU) cores. Generally, in a networking environment, CPU cores can include the processors that perform computational task, etc. required networking device (e.g., switch, router, etc.) operation. For example, CPU core(s) execute instructions for managing data flow (e.g., packet processing, control plane tasks, data plane acceleration, parallel processing, etc.). Ethernet interface block 220 can include an Ethernet interface or medium (e.g., copper or fiber) to facilitate connecting the chiplet to an Ethernet network. Speed of the Ethernet interface or medium can be variable (e.g., depending on the networking application specifications) such as at 1G, 10G, 100G, 200G, 400G, 800G, etc. Internal network interfaces block 260 can include the Ethernet physical (Phys) and media access control (MAC) layers that are compliant with IEE 802.3 standards and integrated, for example, into a network interface card (NIC), Ethernet switch, etc. UCIe block 230 refers to an open industry standard that defines an interface for chiplet-to-chiplet connections within a single IC package. Peripherals block 270 can include memories and buffers. NOC fabric block 250 can include an interconnect infrastructure including dedicated, high-bandwidth routing paths (e.g., routers and links) to provide communication between and, particularly, to move data efficiently between all of the various blocks (and components therein) within the chiplet.

However, in the disclosed embodiments, instead of representing one or more particular subsystems for performing one or more particular networking functions, subsystems block 280 within customizable LE 153 can be customizable. That is, customizable LE 153 can further include a subsystems menu 281. This subsystems menu 281 can include a list of multiple different networking subsystems 282₁-282ₙ, which are selectable for inclusion in a customized network infrastructure chiplet. These networking subsystems can be subsystems typically found in one or more different types of networking applications and configured to perform one or more networking functions. Such networking applications could include any one or more of AI and ML networking applications, industrial networking applications, automotive networking applications, and/or other networking applications needing time sensitive, low latency, lossless real time communication.

For example, the subsystems listed in the subsystems menu 281 can be AI/ML network-specific subsystems, industrial network-specific subsystems, and/or automotive network-specific subsystems. Examples of such networking subsystems that could be included within subsystems menu 281 and selectable for inclusion in a customized network infrastructure chiplet include any of: a host-side AI accelerator; an AI infrastructure scale-up switch (which is compliant with any scale-up technology, such as Ultra Accelerator Link (UALink), Scale-Up Ethernet (SUE), Ethernet for Scale-Up Networking (ESUN), etc.); an AI infrastructure scale-out switch (which is compliant with any scale-out technology, such as Ultra Ethernet Consortium (UEC), etc.); an AI infrastructure scale-across switch (which is compliant with any scale-across technology); an AI infrastructure in-network collective (INC); an Ethernet Data Plane for industrial or automotive networking applications; an Ethernet Switch for industrial or automotive networking applications; an Ethernet Router for industrial or automotive networking applications; an inline real time network packet processor; an inline network security processor (e.g., a transport layer security (TLS) processor); an inline faster and dedicated control plane packet processor; an inline faster telemetry processor; and an inline faster application processor (e.g., a network management processor (NMI)). It should be understood that the list provided above is not exhaustive and any other, now known or subsequently developed, networking subsystems for performing one or more networking functions could be included in the subsystems menu.

Additionally, in the disclosed embodiments, within customizable LE 153, cores block 210 can also be customizable. That is, customizable LE 153 can further include a softcores menu 211. This softcores menu 211 can include a list of multiple different softcores 212₁-212ₘ (also referred to herein as optimized softcores), which are each specifically optimized for improving performance, power and/or area (PPA) of at least one networking function and which are selectable for inclusion in a customized infrastructure chiplet. Those skilled in the art will recognize that a softcore refers to a set of instructions (code) synthesized into programmable logic (e.g., a field-programmable gate array (FPGA)). Because a softcore is code-based (i.e., a set of instructions), it can be customized for a specific networking function or multiple different networking functions. Generally, the optimized softcores include sets of instructions (code) directed to a specific networking function or multiple networking functions and optimized (i.e., specifically designed) to improve performance, power and/or area (PPA) in a networking environment. Such optimized softcores can include, but are not limited to any of the following: in-order to high-performance out-of-order scalable multi-core; a high-efficiency multi-threading core; a high-level operating system (HLOS) core; a real-time operating system (RTOS) core; a core optimized for faster forwarding plane programming; a core optimized for inline processing including packet processing; a core optimized for control plane processing; a core optimized for telemetry processing; a core optimized for management processing; a core optimized for remote procedure call processing; a core optimized for network management interface processing; a core optimized for security; a core optimized for in-network collective processing; a core optimized to run any of applications and agents of the applications; and a core optimized for application-to-network stack interface processing. It should be noted that each of the above-mentioned optimized softcores are directed to one specific networking function. However, it should be understood any two or more of the above-mentioned optimized softcores could instead be combined into a single softcore (i.e., a single set of instructions) directed to two or more specific networking functions. For example, an optimized softcore could be directed to HLOS and RTOS processing, another optimized softcore could be directed to telemetry and management processing, etc. Additionally, it should be understood that the list provided above is not exhaustive and any other now known or subsequently developed, optimized softcores for one or more networking functions could be included on softcores menu 211.

System 100 could further be configured so that during network infrastructure chiplet customization menu selections can be made by a user and/or automatically by processor 120. For example, in some embodiments, processor 120 can receive (e.g., through GUI 131) user selections of subsystem(s) from subsystems menu 281 and of optimized softcore(s) from softcores menu 211. In other embodiments, processor 120 can receive (e.g., through GUI 131) user inputs including specifications for the customized networking infrastructure chiplet (e.g., PPA specifications for the chiplet) and processor 120 can further automatically select subsystem(s) from subsystems menu 281 and optimized softcore(s) from softcores menu 211 in order to best meet those specifications. In still other embodiments, processor 120 can receive (e.g., through GUI 131) user selection(s) for subsystem(s) from subsystems menu 281 and, optionally, user inputs including PPA specifications for the customized networking infrastructure chiplet and processor 120 can further automatically select optimized softcore(s) from softcores menu 211 based on the selected subsystem(s) and, if applicable, based on the PPA specifications.

In any case, using customizable LE 153 along with the selections of subsystem(s) and softcore(s) (which is/are optimized for networking function(s)), processor 120 can generate a design layout 111 for a customized network infrastructure chiplet and can store design layout 111 in memory 110. Design layout 111 can include, for example, the various blocks mentioned above. That is, design layout 111 can include a cores block 210, an Ethernet interface block 220, a UCIe block 230, a NOC fabric block 250, an internal network interfaces block 260, a subsystems block 280 and a peripheral block 270. Within subsystems block 280, design layout 111 will include at least one subsystem (e.g., any of 282₁-282ₙ) selected from subsystems menu 281. Additionally, within cores block 210, design layout 111 will include at least one softcore (set of instructions) optimized for at least one networking function (e.g., any of 212₁-212ₘ) and selected from softcores menu 211.

Design layouts 111 for one or more such customized network infrastructure chiplets can be incorporated (e.g., by the processor 120) into an overall design layout 112 for a packaged device (e.g., for Soc). Customized network infrastructure chiplet(s) and a packaged device (e.g., SOCs) including such customized network infrastructure chiplet(s) manufactured according to the design layouts 111-112 and incorporated subsequently into a network infrastructure.

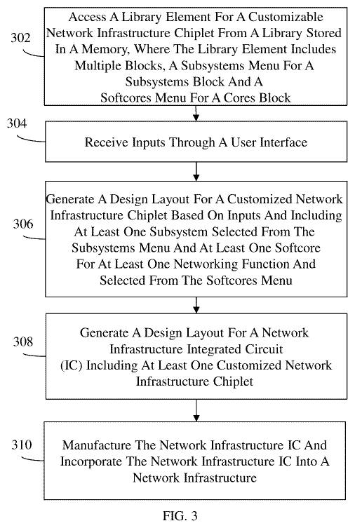

Also disclosed herein are embodiments of a computer-implemented method for designing integrated circuits (ICs) and implemented using the above-described system 100 of FIG. 1. Specifically, referring to the flow diagram of FIG. 3 in combination with FIGS. 1 and 2 discussed in detail above, the method can include accessing, by a processor 120 of system 100 from memory 110, a library 151 including a customizable LE 153 for a customizable network infrastructure chiplet (see process 302). The customizable LE 153 can, as illustrated in FIG. 2, include multiple blocks. These blocks can include but are not limited to: a cores block 210, an Ethernet interface block 220, a Universal Chiplet Interconnect Express (UCIe) block 230; a network-on-chip (NOC) fabric block 250; an internal network interfaces block 260; a peripherals block 270; and a subsystems block 280. The customizable LE 153 can also include: a subsystems menu 281 for subsystems block 280 and including a listing of multiple selectable subsystems 282₁-282ₙ; and a softcores menu 211 for cores block 210 and include a listing of multiple selectable softcores 212₁-212ₘ, each optimized for one or more networking functions. Example subsystems and optimized softcores that can be included in menus 211 and 281 are discussed in detail above with regard to the systems embodiments.

The method can further include receiving (e.g., by processor 120 through GUI 131) user inputs for customization of a networking infrastructure chiplet (see process 304). In some embodiments, at process 304, the method can specifically include receiving (e.g., by processor 120 through GUI 131) user-selections of subsystem(s) from subsystems menu 281 and optimized softcore(s) from softcores menu 211. In other embodiments, at process 304, the method can include: receiving (e.g., by processor 120 through GUI 131) user inputs including specifications for the customized networking infrastructure chiplet (e.g., PPA specifications for the chiplet) and automatically selecting (e.g., by processor 120) subsystem(s) from subsystem menu 211 and optimized softcore(s) from softcores menu 211 to best meet those specifications. In still other embodiments, at process 304, the method can include: receiving (e.g., by processor 120 through GUI 131) user selection(s) for subsystem(s) from subsystems menu 281 and, optionally, user inputs indicating specifications for the customized networking infrastructure chiplet (e.g., PPA specifications for the chiplet); and automatically selecting (e.g., by processor 120) optimized softcore(s) from softcores menu 211 based on the selected subsystem(s) and, optionally, based on the PPA specifications.

The method can further include generating (e.g., by processor 120) a layout 111 for the customized network infrastructure chiplet using customizable LE 153 along with selections of subsystem(s) and optimized softcore(s) made at process 304 (see process 306). The resulting layout 111 can include, for example, a cores block 210, an Ethernet interface block 220, a UCIe block 230, an internal network interfaces block 260, a subsystems block 280, a peripheral block 270, and an NOC fabric block 250 for facilitating communication between the blocks. Within subsystems block 280, layout 111 will include at least one subsystem (e.g., any of 282₁-282ₙ). Additionally, within cores block 210, layout 111 will include at least one softcore (set of instructions) optimized for at least one networking function (e.g., any of 212₁-212ₘ).

The method can further include generating (e.g., by processor 120 and, for example, based on specifications for a network IC) an overall design layout 112 for a packaged device (e.g., for SOC) including one or more such customized network infrastructure chiplets (see process 308). Customized network infrastructure chiplet(s) and a packaged device (e.g., SOCs) including such customized network infrastructure chiplet(s) can further manufactured according to the design layouts 111-112 and incorporated subsequently into a network infrastructure (see process 310).

The design system and method embodiments discussed above provide for the development of a customized network infrastructure chiplet for inclusion in network infrastructures of diverse networking applications (including, but not limited to, AI/ML, industrial and automotive networking applications) within a relatively fast turn-around-time (TAT) while still providing the necessary flexibility for meeting performance, power and/or area (PPA) specifications. More specifically, the disclosed system and method embodiments provide a flexible on-chip solution for a wide range of networking applications needs (e.g., host side, switch side, different topologies or different ethernet technologies solutions for end-to-end network infrastructures), which are not possible with current one functionality system on-chip solutions. Thus, the disclosed design system and method embodiments can be particularly useful for developing network infrastructures for networking applications needing time sensitive, low latency, lossless real time communication. For example, the disclosed embodiments could be employed for building an end-to-end system of: accelerators at host side with memory access needing both remote memory access (RMA) (e.g., load/store) and remote direct memory access (RDMA), on-chip switch/router to build scale-up and scale-out backend networks for data centers (DCs) to connect accelerators in different network topologies, time sensitive networking (TSN) infrastructures for industrial and/or automotive networking applications, etc.

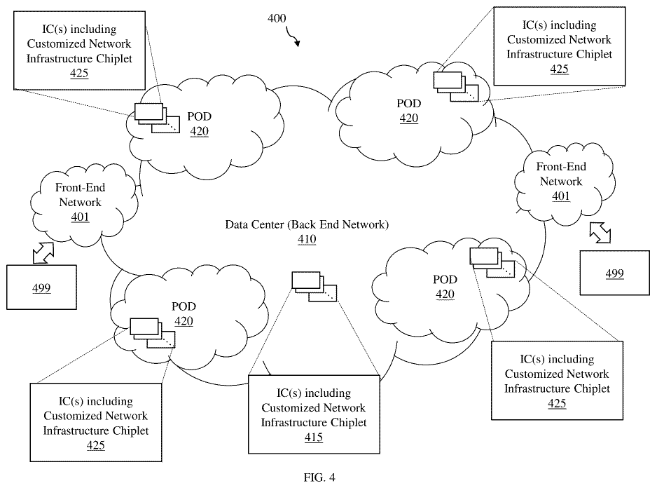

FIG. 4 is a schematic diagram illustrating an example end-to-end network 400 for an AI or ML networking application for which customized network infrastructure chiplet(s) could be developed using the disclosed design system and method embodiments. Generally, in such an end-to-end network 400, users 499 can access a back-end data center network 410 (also referred to herein as a graphic processing unit (GPU) fabric or AI accelerator fabric) via front-end networks 401 in order to perform AI tasks (including a ML tasks). Those skilled in the art will recognize that back-end data center network 410 is a primary component providing high-performance inter-device communication for Al-driven data centers. Back-end data center network 410 can be configured to support the demands of distributed AI workloads (e.g., training and inference) including, but not limited to, distributed memory sharing, gradient aggregation for large language models, collective communications in multi-node AI training, managing RDMA and RMA operations requiring guaranteed delivery, and providing precise congestion control, etc. Back-end data center network 410 can further be configured to provide quality-of-service specifications including, but not limited to, a guaranteed bandwidth (e.g., approximately 400/800 Gbps per device), low latency (e.g., around 2 microseconds (μs)), lossless transmission, and predictable performance under loaded conditions.

Back-end data center network 410 can include a system of interconnected performance optimized datacenters (PODs) 420. For purposes of this disclosure, a POD refers to a self-contained modular unit including server(s), storage, etc. Such PODs allow data centers to grow incrementally by adding new PODs. Typically, a back-end data center network supports either a scale-up network for vertical scaling or a scale-out network for horizontal scaling. A scale-up network typically focuses on accelerator-to-accelerator communication within each POD 420 (e.g., up to 1,024 accelerators) and leverages direct load/store memory access for ultra-low latency operations. A scale-out network typically facilitates communication across PODs 420 (e.g., connecting together thousands of accelerators) and utilizes RDMA for efficient data transfer across pods. The disclosed design system and method can be employed to provide a customized solution that enables both (1) a scale-up network and (2) a scale-out network to operate within back-end data center network 410. For example, the disclosed design system and method can be used to develop customized network infrastructure chiplet(s) 425 to be included packaged device(s) incorporated into PODs 420 to support scale-up network functionality and also to develop customized network infrastructure chiplet(s) 415 to be included in packaged device(s) within the back-end data center network 410 and in communication with PODs 420 to support scale-out network functionality.

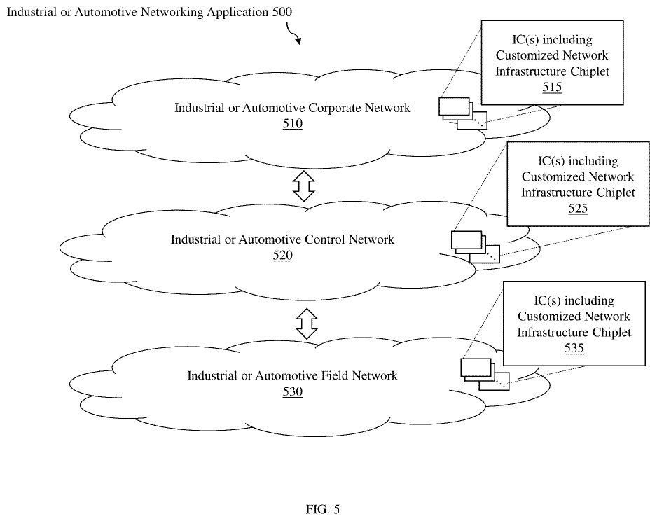

FIG. 5 is a schematic diagram illustrating an example of an industrial or automotive networking application 500 including multiple interconnected networks (e.g., a corporate network 510, a control network 520, and a field network 530). The disclosed design system and method can be employed to provide a flexible and customizable network infrastructure to support different protocols and further to support real time, time sensitive networking (TSN) across the interconnected networks 510, 520, 530. That is, the disclosed design system and method can be used to develop customized network infrastructure chiplet(s) 515, 525 and/or 535 to be included in packaged device(s) incorporated into networks 510, 520 and/or 530, respectively, to support the communication protocols and/or real time TSN.

The example use cases discussed above and illustrated in FIGS. 4 and 5 are provided for illustration purposes and are not intended to be limiting. The disclosed design system and method could be employed in various other networking applications. For example, a network topology refers to the physical and logical layout of nodes and connections therebetween within a communication network. Different network topologies need different functionalities (e.g., host, switch, router, in-network collective (INC), etc.) to be enabled on different nodes. Typically, different mixed functionalities cannot be built in the same packaged device (e.g., the same SOC) and need different solutions for different nodes causing interoperability issues. The disclosed design system and method can be employed to provide programmable and customizable functionalities (e.g., through a combination of selected subsystem(s) and/or optimized softcore(s)), which can be deployed on the same customized network infrastructure chiplet and which provides end-to-end interoperability with high performance.

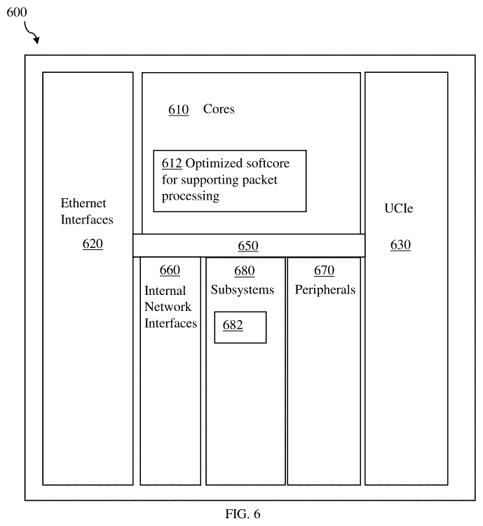

FIG. 6 is a diagram illustrating one example of a design layout 600 for a network infrastructure chiplet customized (e.g., using the disclosed design system and method embodiments) for in-network packet processing. Design layout 600 includes: a cores block 610, an Ethernet interface block 620, a Universal Chiplet Interconnect Express (UCIe) block 630; an internal network interfaces block 660; a peripherals block 670; a subsystems block 680; and a network-on-chip (NOC) fabric block 650 for facilitating communication between the blocks. Design layout 600 can further include, within subsystems block 680, a subsystem and, particularly, a packet processor core 682 (e.g., an inline faster (dedicated) control plane packet processor core). Additionally, within cores block 610, design layout 600 can include at least one optimized softcore(s) 612 for supporting packet processing. Optimized softcore 612 can, for example, be a core optimized for inline processing including packet processing. Such a softcore 612 can include a set of instructions directed to any one or more of the following: efficient packet parsing: pattern matching in incoming packet on specific locations; variable length string/pattern match; efficient hashing including faster hashing, faster hash table lookup and data access, and dynamic hash table update; efficient binary/AVL tree including faster search and update, and dynamic update; efficient radix tree including faster exact or longest prefix search and dynamic update; efficient string database (DB) including variable length string compare and search; rule engine optimization; overlapping prefix match; efficient packet modification including encapsulation/decapsulation and field insertion/removal; faster counter/statistics update and retrievals; faster encryption/decryption; faster DB performance for control plane; transport layer security (TLS) performance improvement; gNMI performance improvement for applications; and enhanced in-network collective (INC) operations.

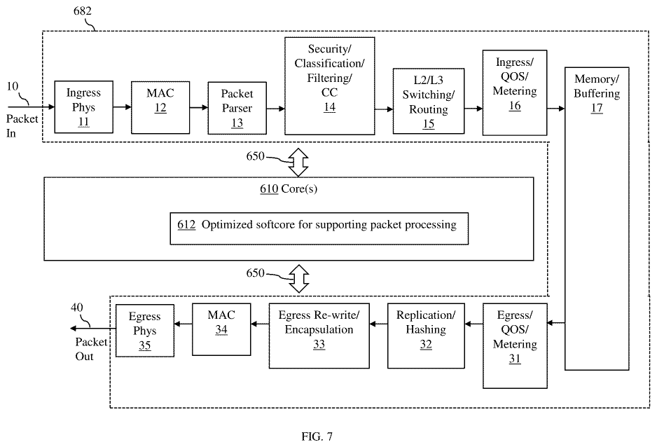

FIG. 7 is a schematic diagram illustrating an example packet processor core 682 in subsystems block 680. As illustrated, packet processor core 682 includes: an ingress branch connected to receive an incoming packet 10 and including multiple series-connected processing stages 11-17 in communication with core block 610 (including softcore 612) via NOC fabric 650; and an egress branch including multiple series-connected processing stages 31-35 also in communication with core block 610 (including softcore 612) via NOC fabric 650 and outputting a processed packet 40. It should be noted that various stages of ingress and egress branches in a packet processor core are generally known in the art. Stages 11-17 and 31-35 shown in FIG. 7 are provided for illustration purposes. FIG. 7 is provided to illustration communication of such stages to with the core block 610 including a softcore 612 optimized to improve packet processing performance (e.g., as noted above) throughout the various stages. It should be understood that the stages illustrated are not intended to be limiting or exhaustive.

Embodiments disclosed herein may be a system, a method, and/or a computer program product. The computer program product may include a computer readable storage medium (or media) having computer readable program instructions thereon for causing a processor to carry out aspects of the disclosed embodiments.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the disclosed embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the disclosed embodiments.

Aspects of the disclosed embodiments are described herein with reference to flowchart illustrations and/or block diagrams of methods, apparatus (systems), and computer program products according to disclosed embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various disclosed embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

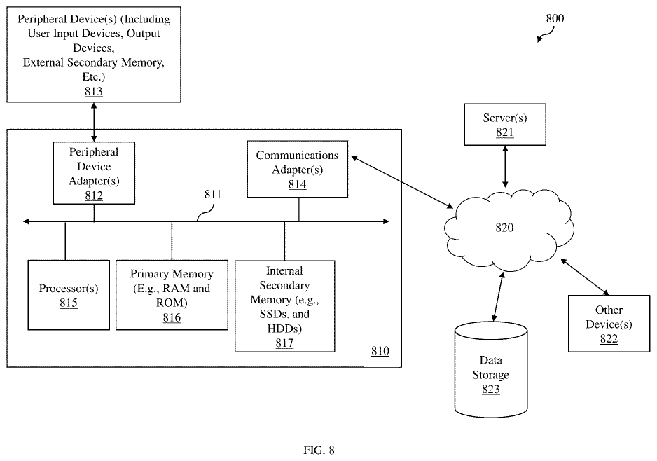

An illustrative hardware environment 800 for implementing aspects of the disclosed systems, methods and computer program products is depicted in FIG. 8. Generally, the hardware environment can include at least one computing device 810 (also referred to herein as a computer). Computer 810 can be, for example, a desktop, laptop, tablet, mobile computing device, etc. Computer 810 can include at least one bus 811. Bus 811 can be connected to various other components of computer 810 and can be configured to facilitate communication between those components.

Computer 810 can include various adapters. The adapters can include one or more peripheral device adapters 812, which are configured to facilitate communications between one or more peripheral devices 813, respectively, and bus 811. Peripheral devices 813 can include user input devices configured to receive user inputs. User input devices can include, but are not limited to, a keyboard, a mouse, a microphone, a touchpad, a touchscreen, a stylus, bio-sensor, a scanner, or any other type of user input device. The peripheral devices 813 can also include additional input devices, such as external secondary memory devices (as discussed in greater detail below). Peripheral devices 813 can also include output devices. The output devices can include, but are not limited to, a printer, a monitor, a speaker, or any other type of computer output device. The adapters can include one or more communications adapters 814 (also referred to herein as a computer network adapters), which are configured to facilitate communications between computer 810 and one or more communications networks 820 (e.g., a wide area network (WAN), a local area network (LAN), the internet, a cellular network, a Wi-Fi network, etc.). Such network(s) 820 can, in turn, facilitate communication between computer 810 and other system components on the network: remote server(s) 821, other device(s) 822 (e.g., computers, laptops, tablets, mobile phones, etc.), remote data storage 823, etc.

Computer 810 can further include at least one processor 815 (also referred to herein as a central processing units (CPU)). Optionally, each CPU 815 can include a CPU cache. Each CPU 815 can be configured to read and execute program instructions.

Computer 810 can further include memory and, particularly, computer-readable storage mediums. The memory can include primary memory 816 and secondary memory. Primary memory 816 can include, but is not limited to, random access memory (RAM) (e.g., volatile memory employed during execution of program operations) and read only memory (ROM) (e.g., non-volatile memory employed during start-up). The RAM can include, but is not limited to, dynamic random access memory (DRAM), static random access memory (SRAM), or any other suitable type of RAM. The ROM can include, but is not limited to, erasable programmable read only memory (EPROM), flash memory, electronically erasable programmable read only memory (EEPROM), programmable read only memory (PROM), or any other suitable type of ROM. The secondary memory can be non-volatile. The secondary memory can include internal secondary memory 817, such as internal solid state drive(s) (SSD(s)) and/or internal hard disk drive(s) (HDD(s), installed within computer 810 and connected to bus 811. The secondary memory can also include external secondary memory connected to or otherwise in communication with the computer 810 (e.g., peripheral devices). The external secondary memory can include, for example, external/portable SSD(s), external/portable HDD(s), flash drive(s), thumb drives, compact disc(s) (CD(s)), digital video disc(s) (DVD(s)), network-attached storage (NAS), storage area network (SAN), or any other suitable non-transitory computer-readable storage media connected to or otherwise in communication with the computer 810. The different functions of primary and secondary memory are well known in the art and, thus, the details thereof have been omitted from this specification in order to allow the reader to focus on the salient aspects of the disclosed embodiments.

In some embodiments, program instructions for performing the disclosed method or a portion thereof, as described above, can be embodied in (e.g., stored in) secondary memory accessible by computer 810. When the program instructions are to be executed (e.g., in response to user inputs to computer 810), required information (e.g., the program instructions and other data) can be loaded into the primary memory (e.g., stored in RAM). CPU 815 can read the program instructions and other data from the RAM and can execute the program instructions. In other embodiments, a client-server model can be employed. In this case, computer 810 can be a client and a remote server 821 in communication with computer 810 over a network 820 can provide, to the client, a service including execution of program instructions for performing the disclosed method or a portion thereof, as described above, in response to user inputs to computer 810.

In view of the foregoing, disclosed herein are various embodiments of a design system and method that ensure flexibility, scalability, and performance and further cater to the unique data and network traffic characteristics of diverse Al/ML, industrial and automotive applications. By addressing different functionalities in one SOC solution, this customizable and interoperable solution sets the foundation for the next generation of Al network infrastructure for different use cases including industrial and automotive networking applications. The core block with optimized softcore(s) provides integrated management and control planes for a network infrastructure in a SOC solution. This provides significant advantages in simplifying network operations and enhancing overall operational efficiency. Additionally, a unified plane streamlines monitoring, configuration, and orchestration processes, thereby reducing the operational overhead associated with managing separate solutions. This integration enables consistent policy enforcement, accelerates troubleshooting, and enhances real-time adaptability to dynamic workloads. Furthermore, a single pane of glass management and unified control plane also fosters better resource utilization, improved security, and scalability by offering a cohesive framework supporting seamless integration of diverse applications and evolving traffic patterns such as in industrial and automotive applications. As workloads evolve in complexity, the flexibility to adapt the infrastructure to diverse organizational needs, AI/ML model types, and traffic patterns becomes paramount. The implementation of a customizable network infrastructure for AI/ML, industrial, and automotive networking applications, as described herein offers the necessary adaptability to maintain high performance across different use cases. Since the complexity of managing flexible solutions can be challenging, the softcore based optimized architecture provides development simplification with long-term benefits of performance, security, and scalability. As a result, the disclose design system and method embodiments support seamless integration of diverse AI/ML, industrial, and automotive networking applications.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system comprising:
a memory storing a library including a library element for a customizable network infrastructure chiplet, wherein the library element includes:
multiple blocks including a subsystems block and a cores block;
a subsystems menu for the subsystems block; and
a softcores menu for the cores block; and
a processor in communication with the memory, wherein the processor generates a layout for a customized network infrastructure chiplet using the library element, and wherein the layout includes:
within the subsystems block, at least one subsystem selected from the subsystems menu; and
within the cores block, at least one softcore for at least one networking function and selected from the softcores menu.

2. The system of claim 1, wherein the processor receives, through a user interface, user selections of the at least one subsystem and the at least one softcore for the at least one networking function.

3. The system of claim 1,
wherein the processor receives, through a user interface, user inputs including specifications for the customized network infrastructure chiplet, and
wherein the processor further automatically selects the at least one subsystem and the at least one softcore for the at least one networking function based on the user inputs.

4. The system of claim 1, wherein the multiple blocks further include:
an Ethernet interface block;
a Universal Chiplet Interconnect Express (UCIe) block;
an internal network interfaces block;
a network-on-chip (NOC) fabric block in communication with all other blocks; and
a peripherals block.

5. The system of claim 1, wherein the subsystems menu includes multiple networking subsystems including for any of artificial intelligence and machine learning networking applications, industrial networking applications, and automotive networking applications.

6. The system of claim 5, wherein the multiple networking subsystems include any of:
a host-side artificial intelligence accelerator;
an artificial intelligence infrastructure scale-up switch ;
an artificial intelligence infrastructure scale-out switch;
an artificial intelligence infrastructure scale-across switch;
artificial intelligence infrastructure in-network collective (INC);
an Ethernet Data Plane;
an Ethernet Switch;
an Ethernet Router;
an inline network packet processor;
an inline network security processor;
an inline control plane packet processor;
an inline telemetry processor; and
an inline application processor.

7. The system of claim 1, wherein the softcores menu includes multiple softcores each optimized for at least one networking function.

8. The system of claim 7, wherein the multiple softcores include any of:
an in-order to high-performance out-of-order scalable multi-core;
a high-efficiency multi-threading core;
a high-level operating system core;
a real-time operating system core;
a core optimized for faster forwarding plane programming;
a core optimized for inline processing including packet processing;
a core optimized for control plane processing;
a core optimized for telemetry processing;
a core optimized for management processing;
a core optimized for remote procedure call processing;
a core optimized for network management interface processing;
a core optimized for security;
a core optimized for in-network collective processing;
a core optimized to run any of applications and agents of the applications; and
a core optimized for application-to-network stack interface processing.

9. A method comprising:
accessing, by a processor from memory, a library including a library element for a customizable network infrastructure chiplet, wherein the library element includes:
multiple blocks including a subsystems block and a cores block;
a subsystems menu for the subsystems block; and
a softcores menu for the cores block; and
generating, by the processor, a layout for a customized network infrastructure chiplet using the library element, wherein the layout includes:
within the subsystems block, at least one subsystem selected from the subsystems menu; and
within the cores block, at least one softcore for at least one networking function and selected from the softcores menu.

10. The method of claim 9, further comprising receiving, by the processor through a user interface, user selections of the at least one subsystem and the at least one softcore for the at least one networking function.

11. The method of claim 9, further comprising:
receiving, by the processor through a user interface, user inputs including specifications for the customized network infrastructure chiplet; and
automatically selecting, by the processor and based on the specifications, the at least one subsystem and the at least one softcore for the at least one networking function.

12. The method of claim 9, wherein the multiple blocks further include:
an Ethernet interface block;
a Universal Chiplet Interconnect Express (UCIe) block;
an internal network interfaces block;
a network-on-chip (NOC) fabric block in communication with all other blocks; and
a peripherals block.

13. The method of claim 9, wherein the subsystems menu includes multiple networking subsystems including for any of artificial intelligence and machine learning networking applications, industrial networking applications, and automotive networking applications.

14. The method of claim 13, wherein the multiple networking subsystems include any of:
a host-side artificial intelligence accelerator;
an artificial intelligence infrastructure scale-up switch;
an artificial intelligence infrastructure scale-out switch;
an artificial intelligence scale-across switch;
artificial intelligence infrastructure in-network collective (INC);
an Ethernet Data Plane;
an Ethernet Switch;
an Ethernet Router;
an inline network packet processor;
an inline network security processor;
an inline control plane packet processor;
an inline telemetry processor; and
an inline application processor.

15. The method of claim 9, wherein the softcores menu includes multiple softcores each optimized for at least one networking function.

16. The method of claim 15, wherein the multiple softcores include any of:
an in-order to high-performance out-of-order scalable multi-core;
a high-efficiency multi-threading core;
a high-level operating system core;
a real-time operating system core;
a core optimized for faster forwarding plane programming;
a core optimized for inline processing including packet processing;
a core optimized for control plane processing;
a core optimized for telemetry processing;
a core optimized for management processing;
a core optimized for remote procedure call processing;
a core optimized for network management interface processing;
a core optimized for security;
a core optimized for in-network collective processing;
a core optimized to run any of applications and agents of the applications; and
a core optimized for application-to-network stack interface processing.

17. A computer program product comprising a non-transitory computer readable storage medium having program instructions embodied therewith, wherein the program instructions are executable by a processor to cause the processor to perform a method and wherein the method comprises:
accessing a library element for a customizable network infrastructure chiplet, wherein the library element is included with a library stored in memory and includes:
multiple blocks including a subsystems block and a cores block;
a subsystems menu for the subsystems block; and
a softcores menu for the cores block; and
generating a layout for a customized network infrastructure chiplet using the library element, wherein the layout includes:
within the subsystems block, at least one subsystem selected from the subsystems menu; and
within the cores block, at least one softcore for at least one networking function and selected from the softcores menu.

18. The computer program product of claim 17, wherein the method further comprises:
receiving, through a user interface, user selections of the at least one subsystem and the at least one softcore for the at least one networking function.

19. The computer program product of claim 17, further comprising:
receiving, through a user interface, user inputs including specifications for the customized network infrastructure chiplet; and
based on the specifications, automatically selecting the at least one subsystem and the at least one softcore for the at least one networking function.

20. The computer program product of claim 17,
wherein the subsystems menu includes multiple networking subsystems including for any of artificial intelligence and machine learning networking applications, industrial networking applications, and automotive networking applications, and
wherein the softcores menu include multiple softcores each optimized for at least one networking function.
